(19) United States
(12) Patent Application Publication
(10) Pub. No.: US 2020/0158807 A1
(43) Pub. Date: May 21, 2020

(54) TEST POSITION ALIGNMENT AND CALIBRATION DEVICE

(71) Applicant: KEST SYSTEMS & SERVICE LTD., HSINCHU CITY (TW)

(72) Inventor: SHENG-TAO PENG, HSINCHU CITY (TW)

(21) Appl. No.: 16/197,652

(22) Filed: Nov. 21, 2018

(51) Int. Cl. G01R 35/00; G01R 1/073

(52) U.S. Cl. CPC G01R 35/005; G01R 1/07364

(57) ABSTRACT

A test position alignment and calibration device comprising a horizontal moving platform and a vertical moving platform driving an aligned device and an image capture beside the aligned device to move. While the calibration probe contacts the aligned device, an electric loop is formed among a calibration probe, a passive element, a light-emitting element, and the aligned device, and the light-emitting element is lighted up, and an actual test position is obtained. The horizontal moving platform moves and aligns the image capture device to the calibration probe to obtain an image detection position. The difference between the image detection position and the actual test position is calculated to obtain an accurate displacement distance, which is the actual distance between the aligned device and the image capture device and will be used in the succeeding tests for achieving a higher accuracy in positioning all the elements.

### BACKGROUND OF THE INVENTION

### Field of the Invention

The present invention relates to a position calibration device, particularly to a test position alignment and calibration device, which is able to determine the displacement distance between the image detection position and the actual test position.

### Description of the Related Art

In semiconductor or integrated circuit (IC) industry, the elements are tested in different stages, no matter in fabrication stages or assemblage stages, to guarantee the yield, quality, and normal operation of the elements.

For an ordinary automatic test apparatus, the test head or grasp-release device is mounted on a horizontal moving platform and a vertical moving platform. In test, the test head or grasp-release device is normally moved by the horizontal moving platform to the above of the tested element beforehand, and then moved downward by the vertical moving platform to contact the tested element and tests it. However, the center of the test head or grasp-release device, which is mounted on the vertical moving platform, cannot match the center of the image capture device. In other words, a displacement distance exists between the image detection position and the actual test position of the test head or grasp-release device. In practical operation, we need to determine the displacement distance exactly. At present, the displacement distance is normally measured manually. However, manual measurement not only consumes much time but also lacks sufficient precision. Besides, manual measurement usually suffers the problems of assemblage and alignment in mechanics. Therefore, manual measurement of the displacement distance has much uncertainty and affects the positioning precision of the entire element.

Accordingly, the present invention proposes a test position alignment and calibration device to overcome the conventional technical problems and provide a higher positioning accuracy.

### SUMMARY OF THE INVENTION

The primary objective of the present invention is to provide a test position alignment and calibration device, which turns on a light-emitting element in a contact way to more accurately obtain the displacement distance between the image detection position and the actual test position, whereby to achieve a higher positioning accuracy.

Another objective of the present invention is to provide a test position alignment and calibration device, which can periodically update the displacement distance, whereby to maintain the positioning accuracy persistently.

In order to achieve the abovementioned objectives, the present invention proposes a test position alignment and calibration device, which is disposed below a vertical moving platform. The vertical moving platform is mounted on a horizontal moving platform. An aligned device disposed on the vertical moving platform, and an image capture device is disposed beside the aligned device. The test position alignment and calibration device of the present invention comprises a base; a calibration probe disposed on the base; at least one passive element; a light-emitting element; and a power module. The horizontal moving platform and the vertical moving platform can drive the aligned device to move and make the aligned device contact the calibration probe. The passive element and the light-emitting element are disposed on the base and electrically connected with the calibration probe. While the calibration probe contacts the aligned device, an electric loop is formed among the calibration probe, the passive element, the light-emitting element and the aligned device. Thereby, the light-emitting element is turned on to acquire an actual test position. The power module is electrically connected with a light-emitting diode and supplies power to the abovementioned elements. The horizontal moving platform makes the image capture device able to align to the calibration probe, whereby to obtain an image detection position. The displacement distance can be accurately obtained via calculating the difference between the image detection position and the actual test position. The accurate displacement distance will be used in the following tests to increase the overall precision.

The bottom of the base has a negative-electrode plate functioning as the grounding terminal. An electric-conduction clamp is electrically connected with the aligned device and the negative-electrode plate to complete electric connection of the electric loop. One end of the electric-conduction clamp has a plug. A socket is disposed on the base corresponding to the plug. The socket is electrically connected with the negative-electrode plate. While the plug is inserted into the socket and the electric-conduction clamp is electrically connected with the aligned device, electric conduction takes place between the aligned device and the negative-electrode plate, which can facilitate the lighting-up of the light-emitting element.

Below, embodiments are described in detail in cooperation with the attached drawings to make easily understood the objectives, technical contents, and accomplishments of the present invention.

### BRIEF DESCRIPTION OF THE DRAWINGS

FIG. 1 is a diagram schematically showing the structure of a test position alignment and calibration device according to one embodiment of the present invention;

FIG. 2 is a top view schematically showing the structure of a test position alignment and calibration device according to one embodiment of the present invention;

FIG. 3 is a diagram schematically showing the circuitry of a test position alignment and calibration device according to one embodiment of the present invention;

FIG. 4A is a diagram schematically showing that a test position alignment and calibration device is disposed on a test platform and aligned to an image capture device according to one embodiment of the present invention;

FIG. 4B is a locally-enlarged view schematically showing that a calibration probe is aligned to an image capture device according to one embodiment of the present invention;

FIG. 5A is a diagram schematically showing that a test position alignment and calibration device is disposed on a test platform and aligned to a test head according to one embodiment of the present invention;

FIG. 5B is a locally-enlarged view schematically showing that a calibration probe is aligned to a test head according to one embodiment of the present invention; and

FIG. 6 is a diagram schematically showing that a calibration probe contacts a test probe according to one embodiment of the present invention.

### DETAILED DESCRIPTION OF THE INVENTION

The test position alignment and calibration device of the present invention uses the horizontal moving platform and the vertical moving platform to precisely determine the image detection position and the actual test position, whereby to acquire a more accurate displacement distance and achieve a higher positioning accuracy.

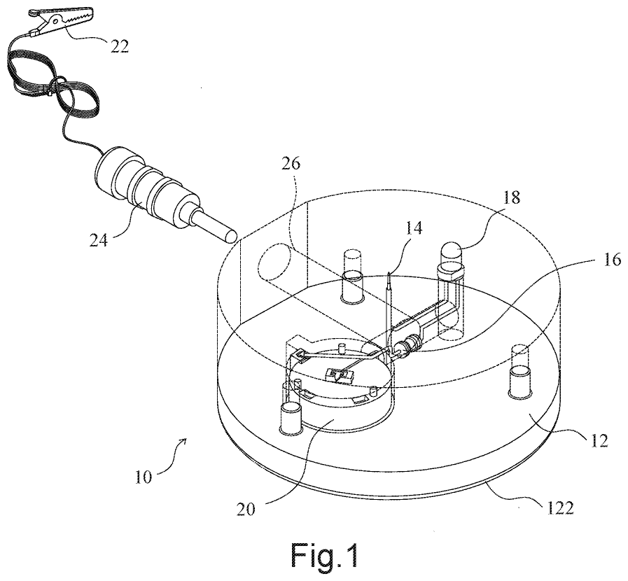

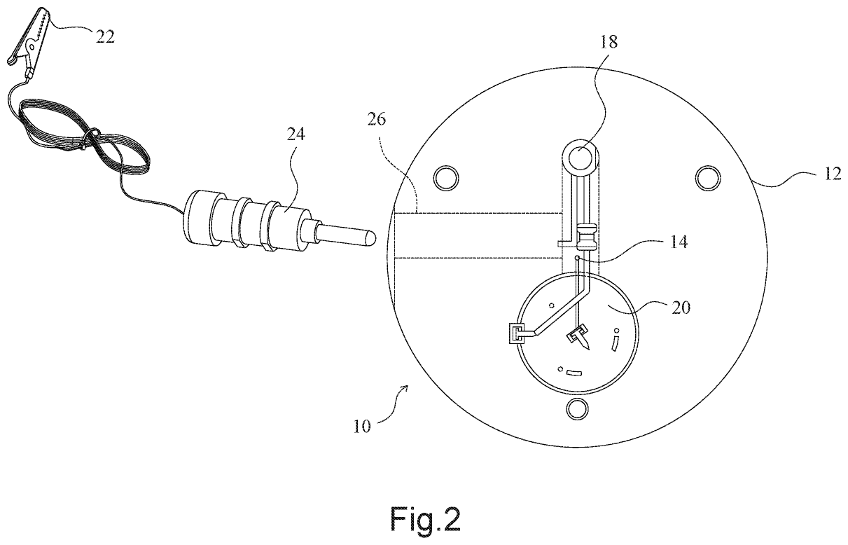

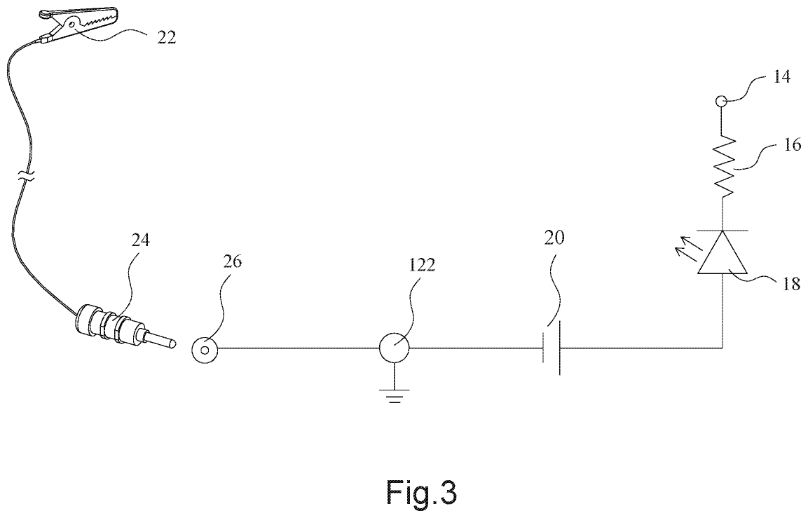

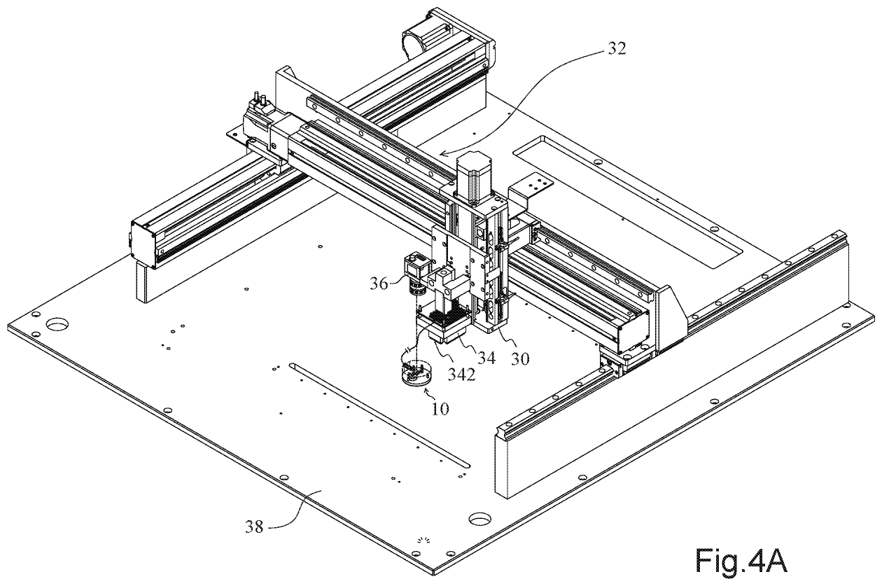

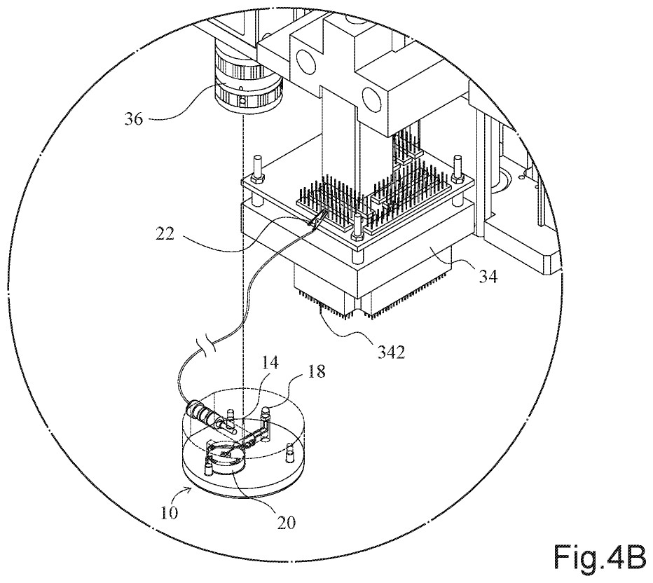

FIG. 1 is a diagram schematically showing the structure of the present invention. FIG. 2 is a top view schematically showing the structure of the present invention. FIG. 3 is a diagram schematically showing the circuitry of the present invention. Refer to FIGS. 1-3, and also refer FIGS. 4A and 4B. The test position alignment and calibration device 10 of the present invention is disposed under a vertical moving platform 30 of a test platform 38. The vertical moving platform 30 is mounted on a horizontal moving platform 32. The horizontal moving platform 32 is the ordinary X-Y axis moving platform, driving the vertical moving platform 30 to move along the directions of the X axis and the Y axis. An aligned device is mounted in the vertical moving platform 30, and an image capture device 36 is disposed beside the aligned device. The aligned device may be a test head or a grasp-release head. In specification, a test head 34 is used to exemplify the aligned device. The test position alignment and calibration device 10 comprises a base 12; a calibration probe 14; at least one passive element, such as a resistor 16; a light-emitting element, such as a light-emitting diode 18; and a power module 20. A negative-electrode plate 122 is arranged on the bottom of the base 12 to function as a grounding terminal. While the present invention is installed in the test platform 38, the present invention and the test platform 38 are grounded jointly. The calibration probe 14 is disposed on the base 12. The test head 34 is moved by the horizontal moving platform 32 and the vertical moving platform 30 to contact the calibration probe 14. The passive element is arranged on the base 12 and electrically connected with the calibration probe 14. The light-emitting element is electrically connected with the resistor 16 and the calibration probe 14, whereby an electric loop is formed to light up the light-emitting diode 18 while the calibration probe 14 contacts the test head 34, and whereby is acquired an actual test position corresponding to the test head 34. The power module 20 is electrically connected with the light-emitting diode 18 and supplies power to the abovementioned elements. The power module 20 may adopt a lithium battery or an equivalent battery.

In one embodiment, the test position alignment and calibration device 10 of the present invention uses an electric-conduction clamp 22. The electric-conduction clamp 22 is electrically connected with the test head 34 and the negative-electrode plate 122 to implement the abovementioned electric loop. One end of the electric-conduction clamp 22 has a plug 24. The base 12 has a socket 26 corresponding to the plug 24. The socket 26 is electrically connected with the negative-electrode plate 122. While the plug 24 is inserted into the socket 26 and the electric-conduction clamp 22 is fixed to the upper portion of a test probe 342 of the test head 34, the test head 34 is electrically connected with the negative-electrode plate 122 to facilitate the electric loop.

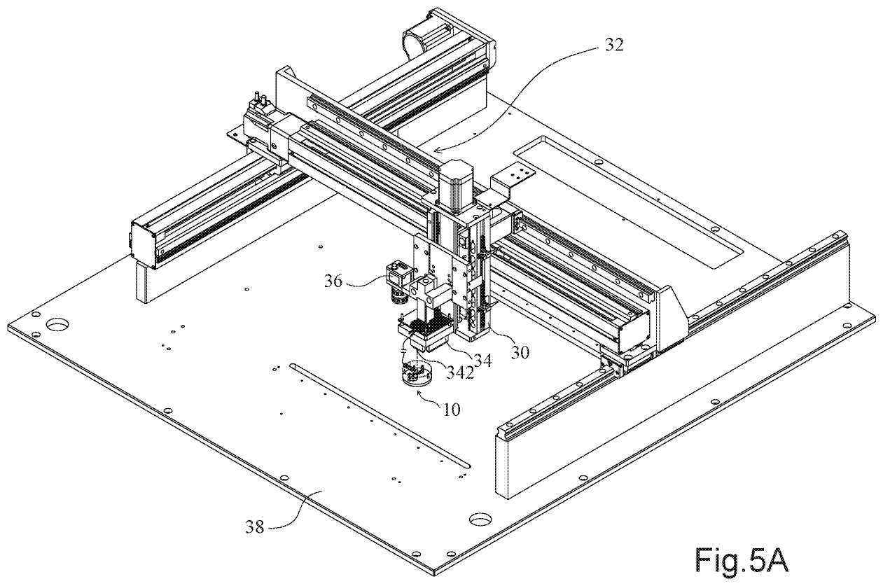

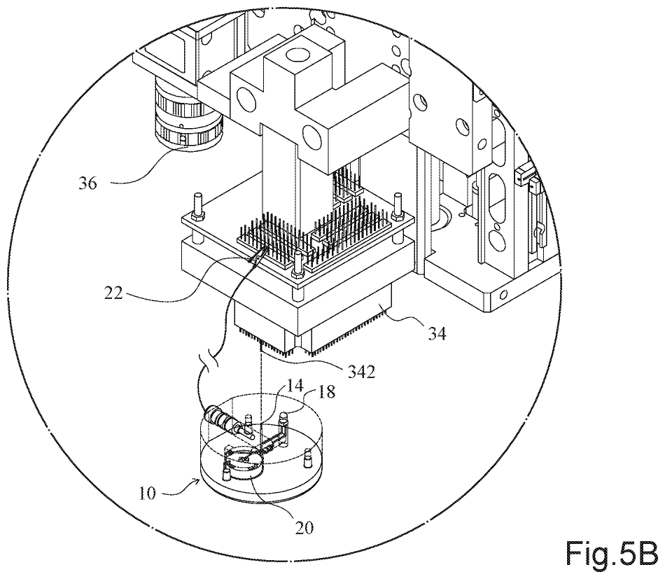

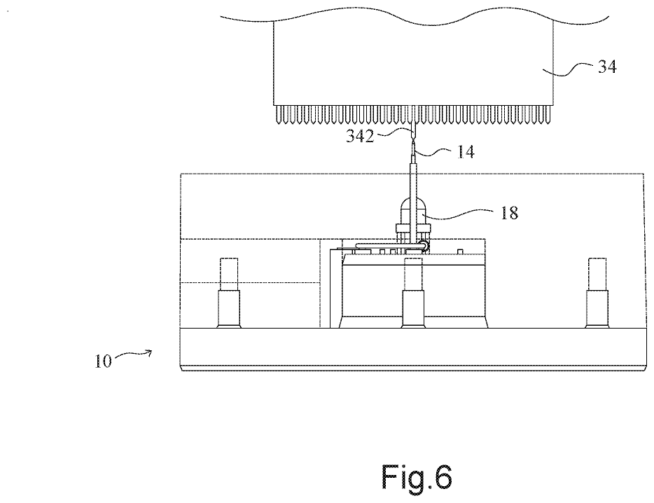

Refer to FIG. 1, FIG. 4A and FIG. 4B for the operation of the test position alignment and calibration device 10 of the present invention. Firstly, place the test position alignment and calibration device 10 on the test platform 38 within the range where the horizontal moving platform 32 can reach. The test position alignment and calibration device 10 should be placed horizontally to avoid sliding. If necessary, the test position alignment and calibration device 10 is secured to the test platform 38 with an adhesive stuck to the back thereof. While the impedance between the test platform 38 and the test position alignment and calibration device 10 is over 500 ohms, the plug 24 of the electric-conduction clamp 22 is inserted into the socket 26, and the electric-conduction clamp 22 is secured to the upper portion of the test probe 342 of the test head 34 to enable the electric conduction between the test head 34 and the negative-electrode plate 122 and thus facilitate the electric conduction of the entire electric loop. After the basic installation is completed, move the horizontal moving platform 32 together with the image capture device 36 to align the center of the image capture device 36 to the calibration probe 14 of the test position alignment and calibration device 10. Next, record the positional values of the horizontal moving platform 32 and obtain an image detection position. Refer to FIG. 1, FIG. 5A and FIG. 5B. Next, move the horizontal moving platform 32 together with the test head 34 to make the test position alignment and calibration device 10 exactly below the test head 34. Next, use the vertical moving platform 30 to move the test head 34 downward until the test probe 342, which is for alignment, contacts the calibration probe 14, as shown in FIG. 6. Thus, the electric conduction of the entire electric loop is enabled, and the light-emitting diode 18 is lighted up to indicate that the contact is done. Next, record the positional values of the horizontal moving platform 32 to obtain an actual test position. Next, calculate the difference between the image detection position and the actual test position to obtain a displacement distance. The displacement distance is the actual distance between the image capture device 36 and the test probe 342 of the probe head 34 and will be used to calibrate positions in the succeeding tests.

In conclusion, the present invention proposes a test position alignment and calibration device, which lights up a light-emitting element after contact is done to assist in obtaining a more accurate displacement distance between the image detection position and the actual test position. Thereby, the present invention can achieve a higher accuracy of positioning. Further, the present invention is convenient to install, and easy to operate. Thus, the present invention is favorable to calibrate positions and update the actual displacement distance periodically. Therefore, the present invention can maintain the positioning accuracy and avoid mechanical errors for a longer period of time.

The embodiments have been described above to demonstrate the technical thoughts and characteristics of the present invention to enable the persons skilled in the art to understand, make, and use the present invention. However, these embodiments are only to exemplify the present invention but not to limit the scope of the present invention. Any equivalent modification or variation according to the spirit of the present invention is to be also included by the scope of the present invention.

What is claimed is:

1. A test position alignment and calibration device, which is disposed below a vertical moving platform, wherein said vertical moving platform is mounted on a horizontal moving platform, and wherein an aligned device is mounted on said vertical moving platform, and wherein an image capture device is mounted beside said aligned device, and wherein said test position alignment and calibration device comprises
a base;
a calibration probe disposed on said base, wherein said horizontal moving platform and said vertical moving platform move said aligned device to contact said calibration probe;
at least one passive element disposed on said base and electrically connected with said calibration probe;
a light-emitting element electrically connected with said passive element and said aligned device, wherein contact of said calibration probe and said aligned device forms an electric loop, lights up said light-emitting element, and determines an actual test position; and
a power module electrically connected with said light-emitting element and supplying power to said light-emitting element.

2. The test position alignment and calibration device according to claim 1, wherein said horizontal moving platform moves said image capture device and aligns said image capture device to said calibration probe to obtain an image detection position and obtain a displacement distance between said image detection position and said actual test position.

3. The test position alignment and calibration device according to claim 1, wherein said aligned device is a test head or a grasp-release head.

4. The test position alignment and calibration device according to claim 1, wherein said horizontal moving platform is an X-Y axis moving platform.

5. The test position alignment and calibration device according to claim 1, wherein said passive element is a resistor.

6. The test position alignment and calibration device according to claim 1, wherein said power module is a lithium battery.

7. The test position alignment and calibration device according to claim 1, wherein a bottom of said base has a negative-electrode plate functioning as a grounding terminal.

8. The test position alignment and calibration device according to claim 7 further comprising an electric-conduction clamp, which is electrically connected with said aligned device and said negative-electrode plate to facilitate electric conduction of said electric loop.

9. The test position alignment and calibration device according to claim 8, wherein one end of said electric-conduction clamp has a plug, and wherein said base has a socket electrically connected with said negative-electrode plate, for electrically connecting said aligned device with said negative-electrode plate.

10. The test position alignment and calibration device according to claim 1, wherein said light-emitting element is a light-emitting diode.
